(19) United States
(12) Patent Application Publication
(10) Pub. No.: US 2014/0110764 A1
(43) Pub. Date: Apr. 24, 2014

(54) Method to control amorphous oxide layer formation at interfaces of thin film stacks for memory and logic components

(71) Applicant: INTERMOLECULAR INC., San Jose, CA (US)

(72) Inventors: Sandip Niyogi, San Jose, CA (US); Sean Barstow, San Jose, CA (US); Dipankar Pramanik, Saratoga, CA (US)

(73) Assignee: Intermolecular Inc., San Jose, CA (US)

(21) Appl. No.: 13/655,838

(22) Filed: Oct. 19, 2012

(51) Int. Cl. H01L 21/28; H01L 29/78

(52) U.S. Cl. 257/288; 438/587; 257/E29.255; 257/E21.19

(57) ABSTRACT

Methods and apparatuses for combinatorial processing are disclosed. Methods of the present disclosure providing a substrate, the substrate comprising a plurality of site-isolated regions. Methods include forming a first capping layer on the surface of a first site-isolated region of the substrate. The methods further include forming a second capping layer on the surface of a second site-isolated region of the substrate. In some embodiments, forming the first and second capping layers include exposing the first and second site-isolated regions to a plasma induced with H₂ and hydrocarbon gases. In some embodiments, methods include applying at least one subsequent process to each site-isolated region. In addition, methods include evaluating results of the films post processing.

### FIELD OF THE INVENTION

The present disclosure relates to methods and apparatuses to control amorphous oxide layer formation at interfaces of thin film stacks for memory and logic components.

### BACKGROUND

In semiconductor devices, native or amorphous oxide films often form on the surface of semiconductor substrates due to exposure to air or ambient conditions during “queue times”—a semiconductor wafer's waiting period between processing steps. Native or amorphous oxide films may also form on a semiconductor substrate when exposed to water or other chemicals.

Generally, native or amorphous oxide films on semiconductor substrates are undesirable because they tend to increase the electrical resistance at the contact interface between the exposed conductor surface and subsequently deposited electrically conducting materials.

Conventional solutions to remove native or amorphous oxide films from semiconductor substrates involve depositing a transition metal layer on the metal oxide layer to serve as an oxygen gettering material. However, depositing an oxygen gettering layer may change the work function of the film stack which requires more thin film layers and additional complex processing to modulate electrostatic potentials to achieve optimal device characteristics.

In addition, conventional methods to remove native oxide films have incorporated HF etching of interface oxide prior to metal oxide deposition. However, wet etching with HF was found to cause heterogeneous growth of metal oxide films.

Further developments and improvements, particularly innovations that accomplish native and amorphous oxide prevention or removal in semiconductor manufacturing, are needed. The present disclosure addresses such a need.

### SUMMARY OF THE DISCLOSURE

The following summary is included in order to provide a basic understanding of some aspects and features of the present disclosure. This summary is not an extensive overview of the disclosure and as such it is not intended to particularly identify key or critical elements of the disclosure or to delineate the scope of the disclosure. Its sole purpose is to present some concepts of the disclosure in a simplified form as a prelude to the more detailed description that is presented below.

Methods and apparatuses for combinatorial processing are disclosed. Methods of the present disclosure providing a substrate, the substrate comprising a plurality of site-isolated regions. Methods include forming a first capping layer on the surface of a first site-isolated region of the substrate. The methods further include forming a second capping layer on the surface of a second site-isolated region of the substrate. In some embodiments, forming the first and second capping layers include exposing the first and second site-isolated regions to a plasma induced with H₂ and hydrocarbon gases. In some embodiments, methods include applying at least one subsequent process to each site-isolated region. In addition, methods include evaluating results of the films post processing.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale. The techniques of the present disclosure can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 illustrates a cross-sectional view of a semiconductor device.

FIG. 5 is a method for controlling native or amorphous oxide layer formation.

FIG. 6 illustrates a cross-sectional view of a substrate having a capping layer disposed thereon.

FIG. 7 illustrates a cross-sectional view of a semiconductor device.

FIG. 8 illustrates an example of a large area ALD or CVD showerhead used for combinatorial processing.

FIG. 9 illustrates a bottom view of two examples of a small spot showerhead apparatus.

FIG. 10 illustrates one example of a pattern of site-isolated regions that may be processed using a small spot showerhead apparatus.

FIGS. 11A-11D illustrates an exemplary deposition sequence for forming multilayer film stacks in a combinatorial fashion.

FIGS. 12A-12D illustrates an exemplary deposition sequence for forming multilayer film stacks in a combinatorial fashion.

FIGS. 13A-13D illustrates an exemplary deposition sequence for forming multilayer film stacks in a combinatorial fashion.

FIG. 14 shows an illustrative embodiment of an apparatus enabling combinatorial processing.

FIG. 15 illustrates a combinatorial processing system including an alternative showerhead for performing combinatorial material deposition.

### DETAILED DESCRIPTION

Methods and apparatuses for combinatorial processing are disclosed. Methods of the present disclosure providing a substrate, the substrate comprising a plurality of site-isolated regions. Methods include forming a first capping layer on the surface of a first site-isolated region of the substrate. The methods further include forming a second capping layer on the surface of a second site-isolated region of the substrate. In some embodiments, forming the first and second capping layers include exposing the first and second site-isolated regions to a plasma induced with H₂ and hydrocarbon gases. In some embodiments, methods include applying at least one subsequent process to each site-isolated region. In addition, methods include evaluating results of the films post processing.

Before the present disclosure is described in detail, it is to be understood that unless otherwise indicated this disclosure is not limited to specific layer compositions or surface treatments. It is also to be understood that the terminology used herein is for the purpose of describing particular embodiments only and is not intended to limit the scope of the present disclosure.

It must be noted that as used herein and in the claims, the singular forms “a,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, coated silicon, other semiconductor materials, glass, polymers, metal foils, etc. The term “substrate” or “wafer” may be used interchangeably herein. Semiconductor wafer shapes and sizes may vary and include commonly used round wafers of 2″, 4″, 200 mm, or 300 mm in diameter.

The term “remote plasma source” as used herein refers to a plasma generator (e.g., an rf or microwave plasma generator) located at a distance from a deposition or treatment location sufficient to allow some filtering of the plasma components. For example, the density of ions and electrons can be adjusted by distance, and electrons and ions can also be filtered using suitable electrode configurations, such as a grounded metal showerhead so that only atomic or molecular radicals reach the substrate.

It is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006; U.S. Pat. No. 7,824,935 filed on Jul. 2, 2008; U.S. Pat. No. 7,871,928 filed on May 4, 2009; U.S. Pat. No. 7,902,063 filed on Feb. 10, 2006; and U.S. Pat. No. 7,947,531 filed on Aug. 28, 2009 which are all herein incorporated by reference for all purposes. Systems and methods for HPC™ processing are further described in U.S. patent application Ser. No. 11/352,077 filed on Feb. 10, 2006, claiming priority from Oct. 15, 2005; U.S. patent application Ser. No. 11/419,174 filed on May 18, 2006, claiming priority from Oct. 15, 2005; U.S. patent application Ser. No. 11/674,132 filed on Feb. 12, 2007, claiming priority from Oct. 15, 2005; U.S. patent application Ser. No. 11/674,137 filed on Feb. 12, 2007; and U.S. patent application Ser. No. 13/302,730 filed on Nov. 22, 2011 claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

HPC™ processing techniques have been adapted to the development and investigation of absorber layers and buffer layers for TFPV solar cells as described in U.S. patent application Ser. No. 13/236,430 filed on Sep. 19, 2011, entitled “COMBINATORIAL METHODS FOR DEVELOPING SUPERSTRATE THIN FILM SOLAR CELLS” and is incorporated herein by reference for all purposes.

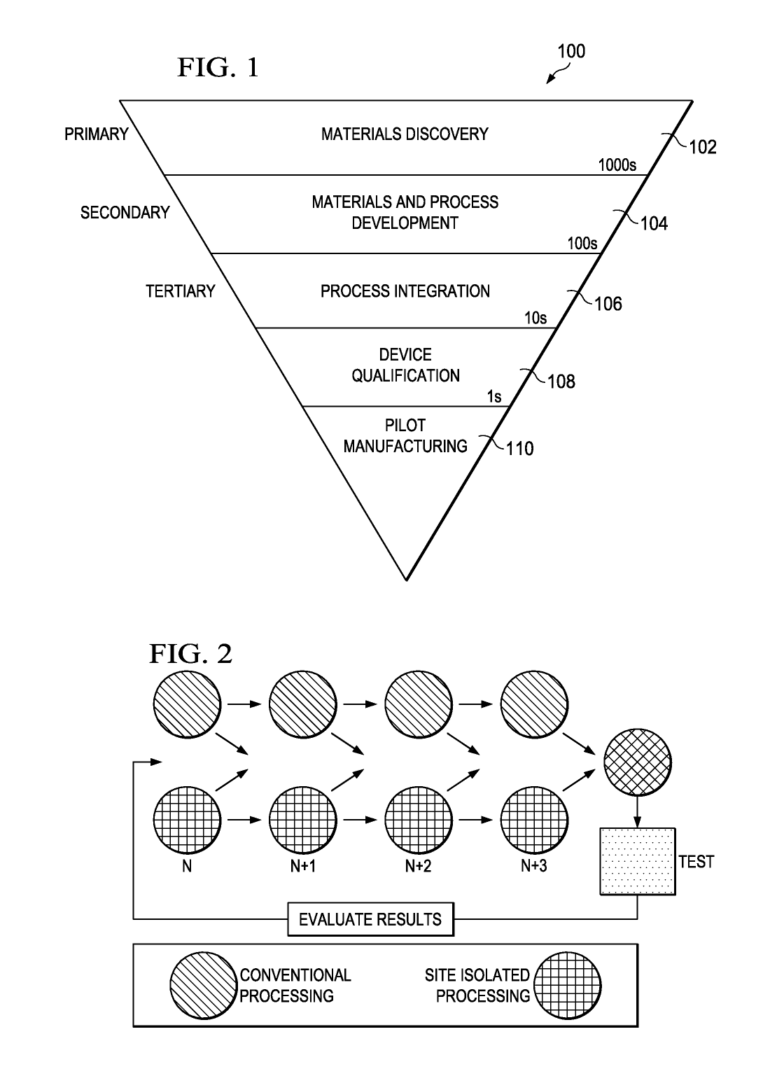

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a material's discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e. microscopes).

The materials and process development stage, 104, may evaluate hundreds of materials (i.e. a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from HPC™ techniques described in U.S. patent application Ser. No. 11/674,137 filed on Feb. 12, 2007 which is hereby incorporated for reference for all purposes. Portions of the '137 application have been reproduced below to enhance the understanding of the present disclosure.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete site-isolated region. Furthermore, while different materials or unit processes may be used for corresponding layers or steps in the formation of a structure in different site-isolated regions of the substrate during the combinatorial processing, the application of each layer or use of a given unit process is substantially consistent or uniform throughout the different site-isolated regions in which it is intentionally applied. Thus, the processing is uniform within a site-isolated region (inter-region uniformity) and between site-isolated regions (intra-region uniformity), as desired. It should be noted that the process can be varied between site-isolated regions, for example, where a thickness of a layer is varied or a material may be varied between the site-isolated regions, etc., as desired by the design of the experiment.

The result is a series of site-isolated regions on the substrate that contain structures or unit process sequences that have been uniformly applied within that site-isolated region and, as applicable, across different site-isolated regions. This process uniformity allows comparison of the properties within and across the different site-isolated regions such that the variations in test results are due to the varied parameter (e.g., materials, unit processes, unit process parameters, hardware details, or process sequences) and not the lack of process uniformity. In the embodiments described herein, the positions of the discrete site-isolated regions on the substrate can be defined as needed, but are preferably systematized for ease of tooling and design of experimentation. In addition, the number, variants and location of structures within each site-isolated region are designed to enable valid statistical analysis of the test results within each site-isolated region and across site-isolated regions to be performed.

FIG. 2 is a simplified schematic diagram illustrating a general methodology for combinatorial process sequence integration that includes site isolated processing and/or conventional processing in accordance with one embodiment of the disclosure. In one embodiment, the substrate is initially processed using conventional process N. In one exemplary embodiment, the substrate is then processed using site isolated process N+1. During site isolated processing, an HPC™ module may be used, such as the HPC module described in U.S. patent application Ser. No. 11/352,077 filed on Feb. 10, 2006, which is incorporated herein by reference for all purposes. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different site-isolated regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from site-isolated region to site-isolated region on the substrate. Thus, for example, when exploring materials, a processing material delivered to a first and second site-isolated regions can be the same or different. If the processing material delivered to the first site-isolated region is the same as the processing material delivered to the second site-isolated region, this processing material can be offered to the first and second site-isolated regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used may be varied.

As mentioned above, within a site-isolated region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the site-isolated regions. It should be appreciated that a site-isolated region may be adjacent to another region in one embodiment or the site-isolated regions may be isolated and, therefore, non-overlapping. When the site-isolated regions are adjacent, there may be a slight overlap wherein the materials or precise process interactions are not known, however, a portion of the site-isolated regions, normally at least 50% or more of the area, is uniform and all testing occurs within that site-isolated region. Further, the potential overlap is only allowed with material of processes that will not adversely affect the result of the tests. Both types of site-isolated regions are referred to herein as site-isolated regions or discrete site-isolated regions.

Substrates may be a conventional round 200 mm, 300 mm, or any other larger or smaller substrate/wafer size. In other embodiments, substrates may be square, rectangular, or other shape. One skilled in the art will appreciate that substrate may be a blanket substrate, a coupon (e.g., partial wafer), or even a patterned substrate having predefined site-isolated regions. In another embodiment, a substrate may have site-isolated regions defined through the processing described herein.

Software is provided to control the process parameters for each wafer for the combinatorial processing. The process parameters comprise selection of one or more source gases for the plasma generator, plasma filtering parameters, exposure time, substrate temperature, power, frequency, plasma generation method, substrate bias, pressure, gas flow, or combinations thereof.

Plasmas are widely used for a variety of treatment and layer deposition tasks in semiconductor fabrication. These applications include subtractive processes such as wafer precleaning, contaminant removal, native oxide removal, photoresist removal, as well as additive processes such as deposition, oxidation, nitridation, or hydridation of a layer both during and after formation. “Remote” plasma sources are frequently used, where the plasma generator is located at some distance from the surface to be treated or substrate on which a layer is to be formed. The distance allows some adjusting of the charged particles in the plasma. For example, the density of ions and electrons can be adjusted by distance, the electrons and ions can be removed from the generated plasma using suitable electrode configurations such as a grounded metal showerhead, so that, for example, only atomic radicals and molecule radicals (but not ions) reach the substrate.

The plasma generator for a remote plasma source can use any known means of pumping energy into atoms or molecules to ionize them and create a plasma. The energy source can be, for example, electromagnetic energy such as microwaves or other radio frequency energy or lasers.

Conventional systems using remote plasma sources were designed to treat the entire area of a substrate such as a 300 mm wafer. Combinatorial processing is difficult and expensive when the entire area of a substrate can only receive a single process variation. Embodiments of the present disclosure overcome this limitation by providing a remote plasma source, an associated substrate positioning system, and a site isolation system that allows a selected site-isolated region of a substrate to be processed while the remaining site-isolated regions of the substrate are protected from exposure to the plasma and reactive radical species unless or until such exposure is intended.

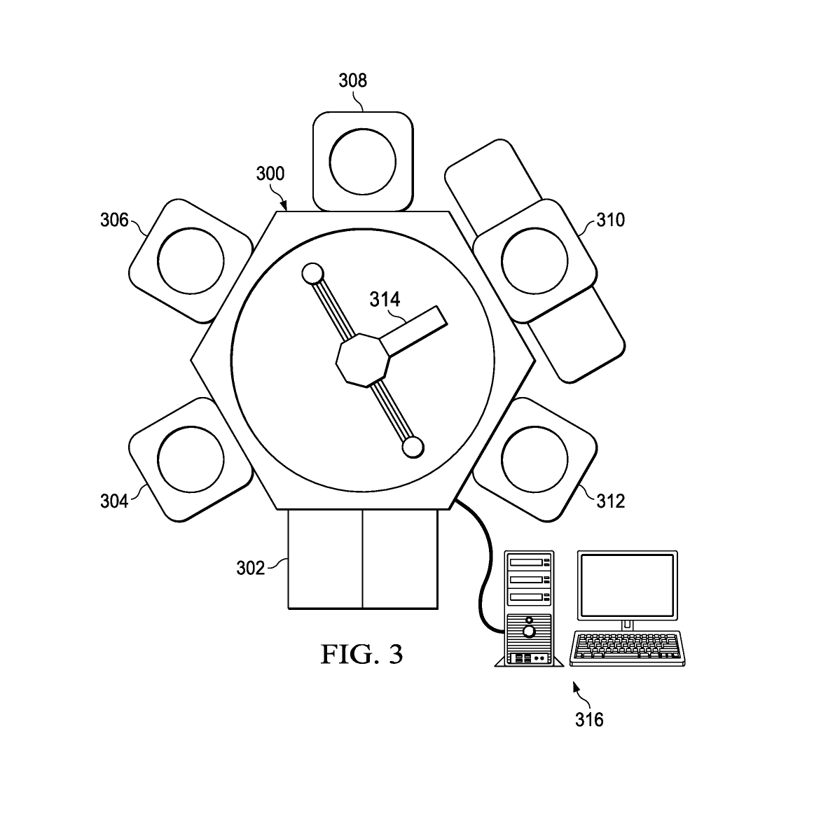

FIG. 3 is a simplified schematic diagram illustrating an integrated high productivity combinatorial (HPC) system in accordance with some embodiments of the disclosure. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. application Ser. Nos. 11/672,473 and 11/672,478, the entire disclosures of which are herein incorporated by reference for all purposes. In a HPC system, a plurality of methods may be employed to deposit material upon a substrate employing combinatorial processes.

According to some embodiments, a method of combinatorial processing of a substrate is provided in which site-isolated sputter deposition and plasma etching are carried out in the same process chamber. The site-isolated sputter deposition may be site-isolated co-sputtering deposition. Cleaning, site-isolated sputter deposition and plasma etching may be carried out in the same process chamber. Cleaning, site-isolated sputter deposition and plasma etching, and full wafer sputter deposition may be carried out in the same process chamber.

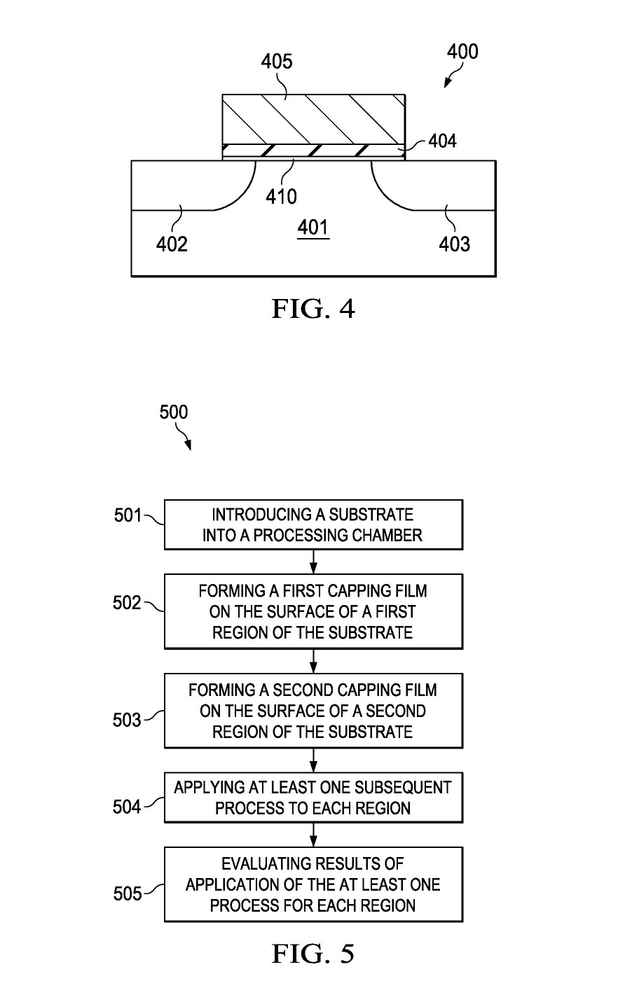

FIG. 4 illustrates a cross-sectional view of a semiconductor device 400. As shown, semiconductor device 400 features conventional transistor gate features such as a source 402, drain 403, and gate stack (dielectric film 404 and gate electrode 405) disposed thereon.

Most notably, a native or amorphous oxide 410 is present at the interface between the substrate 401 and the gate stack. In some semiconductor devices, the thickness of the native or amorphous oxide 410 can exceed 20 angstroms which may be too thick for current semiconductor device technologies.

### Blanket Deposition

FIG. 5 is a method 500 for controlling native or amorphous oxide layer formation. As shown, method 500 begins with block 501 which provides introducing a substrate into a processing chamber. In some embodiments, the substrate includes a semiconductor material. In addition, the processing chamber may be any tool which can provide plasma enhanced chemical vapor deposition (PECVD).

A plasma enhanced CVD system suitable for blanket deposition and site isolated combinatorial processing is described in U.S. patent application Ser. No. 12/433,842, now U.S. Pat. No. 8,129,288, filed on Apr. 30, 2009, and claiming priority to U.S. Provisional Patent Application No. 61/050,159 filed on May 2, 2008, which are both herein incorporated by reference for all purposes. Examples of process parameters that may be varied include gas composition, gas concentration, temperature, plasma power, pressure, gas flow rate, substrate bias, etc.

Next, according to block 502, some embodiments include forming a first capping film or layer on the surface of the substrate. In some embodiments, first capping layer is formed by using a PECVD process. For example, a plasma generated during a PECVD process includes hydrogen gas and methane which creates silicon-oxide, silicon-carbon, and silicon-hydrogen bonds at the gate stack/substrate interface of the semiconductor device when the substrate comprises silicon. It should be understood that the when the substrate contains materials (e.g. substrate S), other than silicon, one or more of S-Oxide, S-Carbon, and S-Hydrogen bonds are present at the gate stack/substrate interface of the semiconductor device.

Block 503 provides forming a second capping film or layer on the surface of the substrate. In some embodiments, second capping layer is formed by the same process used to form first capping layer as previously described.

In some embodiments, when capping layer(s) are formed, the plasma power within the processing chamber may be in the range of 500-1900 Watts and the plasma frequency may be in the range of 50 KHz to 2 GHz. In addition, the pressure within the processing chamber may be in the range of 0.1-5 Torr according to some embodiments. In some embodiments, the temperature within the processing chamber when forming the capping layer(s) may be in the range of room temperature to 500° C. The variation of process parameters previously described my help control the thickness and the chemical structure of the capping layer(s). In some embodiments, the thickness of each capping layer may be a pre-defined fraction of the thickness of the gate stack.

In some embodiments, the plasma generated during the PECVD process removes (e.g. via a plasma etch) any native or amorphous oxide present on the surface of the substrate prior to forming the first and second capping layers on the substrate. For example, prior to depositing the first and second capping layers, the substrate's surface is exposed to a plasma and thereby subjected to bombardment by energetic ions whose kinetic energy may vary from a few electron volts (eV) to hundreds of electron volts according to some embodiments.

Next, some embodiments include applying at least one subsequent process according to block 504. In some embodiments, applying at least one subsequent process includes additional processing to complete a transistor gate stack. For example, a high-k dielectric layer and a metal gate electrode may be formed on the capping layer(s) disposed on the surface of the semiconductor substrate.

Finally, method 500 concludes with block 505 which provides evaluating results of application of the at least one process. Evaluating results of the application of the at least one process includes testing each capping layer's physical and electrical characteristics and performance. It should be understood that the present disclosure is not limited to blocks 501-505 of the flowchart 500.

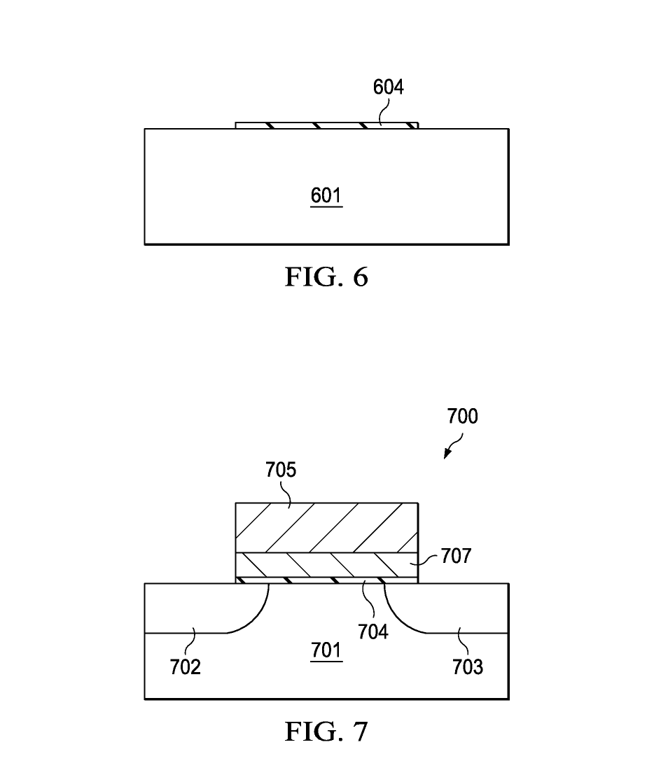

FIG. 6 illustrates a cross-sectional view of a substrate 601 having a capping layer 604 disposed thereon. As shown, capping layer 604 has been patterned according to conventional lithography and etch methods known by those skilled in the art.

In some embodiments, capping layer 604 is formed by a plasma enhanced CVD process as previously described. In some embodiments, the thickness of the capping layer formed on the substrate is in the range of 5-15 nanometers. In some embodiments, the thickness of the capping layer is approximately 10 nanometers.

Furthermore, each capping layer 604 includes carbon, oxygen, hydrogen, and nitrogen atoms therein according to some embodiments. In particular, each capping layer 604 includes silicon-oxide, silicon-carbon, silicon-hydrogen, and silicon-nitrogen bonds according to some embodiments. In some embodiments, the presence of silicon-oxygen, silicon-carbon, and silicon-hydrogen bonds within capping layer 604 is a result of a plasma enhanced CVD process. In some embodiments, the presence of silicon-hydrogen bonds within the capping layer(s) consumes, terminates, or removes any native or amorphous on the surface of the substrate.

In addition, plasma generated during the process is induced with H₂ gas and hydrocarbon gas (e.g., CH₄) therein according to some embodiments. For example, suitable hydrocarbons may include but are not limited to methane, ethane, propane, butane, pentane, hexane, octane, their variations, or combinations thereof.

In addition, the presence of silicon-nitrogen bonds within each capping layer 604 may be a result of a subsequent NH₃ annealing process. The thickness of capping layer 604 may be formed such that it adequately serves to getter and prevent native or amorphous oxide from forming on substrate 601 according to embodiments of the present disclosure.

FIG. 7 illustrates a cross-sectional view of a semiconductor device 700 according to some embodiment of the present disclosure. Semiconductor device 700 includes a source 702, drain 703, and gate stack (dielectric layer 707 and gate electrode 705), disposed upon capping layer 704. In some embodiments, capping layer 704 exhibits properties previously described. In some embodiments, the thickness of capping layer 704 may be a pre-defined fraction of the thickness of the gate stack.

### Combinatorial Processing

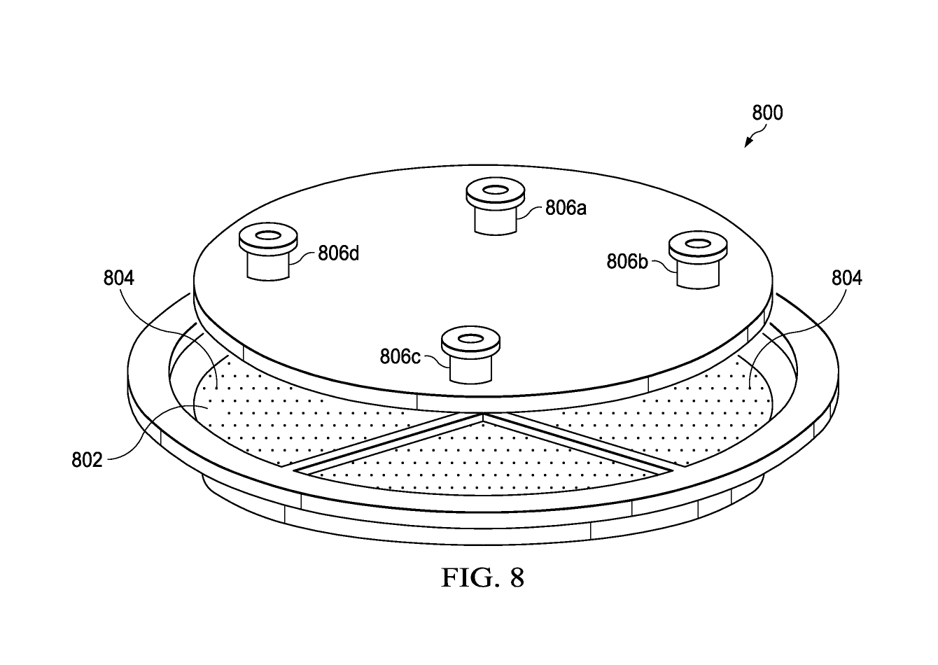

FIG. 8 illustrates an example of a large area ALD or CVD showerhead 800 used for combinatorial processing. Details of this type of showerhead and its use may be found in U.S. patent application Ser. No. 12/013,729 entitled “Vapor Based Combinatorial Processing” filed on Jan. 14, 2008 and claiming priority to Provisional Application No. 60/970,199 filed on Sep. 5, 2001; U.S. patent application Ser. No. 12/013,759 entitled “Vapor Based Combinatorial Processing” filed on Jan. 14, 2008 and claiming priority to Provisional Application No. 60/970,199 filed on Sep. 5, 2001; and U.S. patent application Ser. No. 12/205,578 entitled “Vapor Based Combinatorial Processing” filed on Sep. 5, 2008 which is a Continuation application of the U.S. patent application Ser. No. 12/013,729 and claiming priority to Provisional Application No. 60/970,199 filed on Sep. 5, 2001, all of which are herein incorporated by reference for all purposes.

The large area ALD or CVD showerhead, 800, illustrated in FIG. 8 comprises four regions, 802, used to deposit materials on a substrate. As an example, in the case of a round substrate, four different materials and/or process conditions could be used to deposit materials in each of the four quadrants of the substrate (not shown). Precursor gases, reactant gases, reactant gases, purge gases, etc. are introduced into each of the four regions of the showerhead through gas inlet conduits 806a-806d. For simplicity, the four regions, 802, of showerhead, 800, have been illustrated as being a single chamber. Those skilled in the art will understand that each region, 802, of showerhead, 800, may be designed to have two or more isolated gas distribution systems so that multiple reactive gases may be kept separated until they react at the substrate surface. Also for simplicity, on a single gas inlet conduit, 806a-806d, is illustrated for each of the four regions. Those skilled in the art will understand that each region, 802, of showerhead, 800, may have multiple gas inlet conduits. The gases exit each region, 802, of showerhead, 800, through holes, 804, in the bottom of the showerhead. The gases then travel to the substrate surface and react at the surface to deposit a material, etch an existing material on the surface, clean contaminants found on the surface, react with the surface to modify the surface in some way, etc. The showerhead illustrated in FIG. 8 is operable to be used with any ALD or plasma enhanced ALD technology.

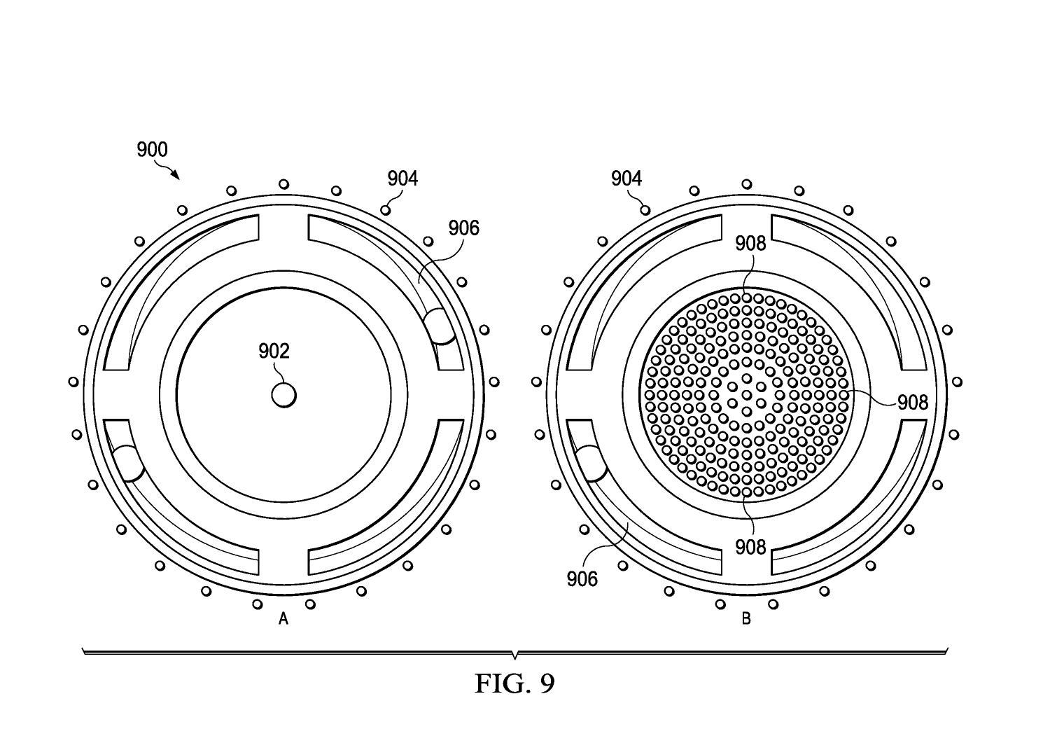

As discussed previously, showerhead, 800, in FIG. 8 results in a deposition (or other process type) on a relatively large region of the substrate. In this example, a quadrant of the substrate. To address the limitations of the combinatorial showerhead illustrated in FIG. 8, small spot showerheads have been designed—see FIG. 9.

FIG. 9 illustrates a bottom view of two examples of a small spot showerhead apparatus 900. The small spot showerhead configuration, A, illustrated in FIG. 9 comprises a single gas distribution port, 902, in the center of the showerhead for delivering reactive gases to the surface of the substrate. The small size of the small spot showerhead and the behavior of the technologies envisioned to use this showerhead ensure that the uniformity of the process on the substrate is adequate using the single gas distribution port. However, the small spot showerhead configuration, B, illustrated in FIG. 9 comprises a plurality of gas distribution ports, 908, for delivering reactive gases to the surface of the substrate. This configuration may be used to improve the uniformity of the process on the substrate if required.

Each small spot showerhead is surrounded by a plurality of purge holes, 904. The purge holes introduce inert purge gases (i.e. Ar, N₂, etc.) around the periphery of each small spot showerhead to insure that the regions under each showerhead may be processed in a site isolated manner. The gases, both the reactive gases and the purge gases, are exhausted from the process chamber through exhaust channels, 906, that surround each of the showerheads. The combination of the purge holes, 904, and the exhaust channels, 906, ensure that each region under each showerhead may be processed in a site-isolated manner. The diameter of the small spot showerhead (i.e. the diameter of the purge ring) may vary between about 40 mm and about 100 mm. Advantageously, the diameter of the small spot showerhead is about 65 mm.

Using a plurality of small spot showerheads as illustrated in FIG. 9 allows a substrate to be processed in a combinatorial manner wherein different parameters may be varied as discussed above. Examples of the parameters comprise process material composition, process material amounts, reactant species, processing temperatures, processing times, processing pressures, processing flow rates, processing powers, processing reactant compositions, the rates at which the reactions are quenched, atmospheres in which the processes are conducted, an order in which materials are deposited, etc.

FIG. 10 illustrates one example of a pattern of site-isolated regions 1001 that may be processed using a small spot showerhead apparatus. In FIG. 10, the substrate 1000 is still generally divided into four quadrants and within each quadrant, three site-isolated regions 1001 may be processed using small spot showerheads as illustrated in FIG. 10, yielding twelve site-isolated regions 1001 on the substrate 1000. Therefore, in this example, twelve independent experiments could be performed on a single substrate.

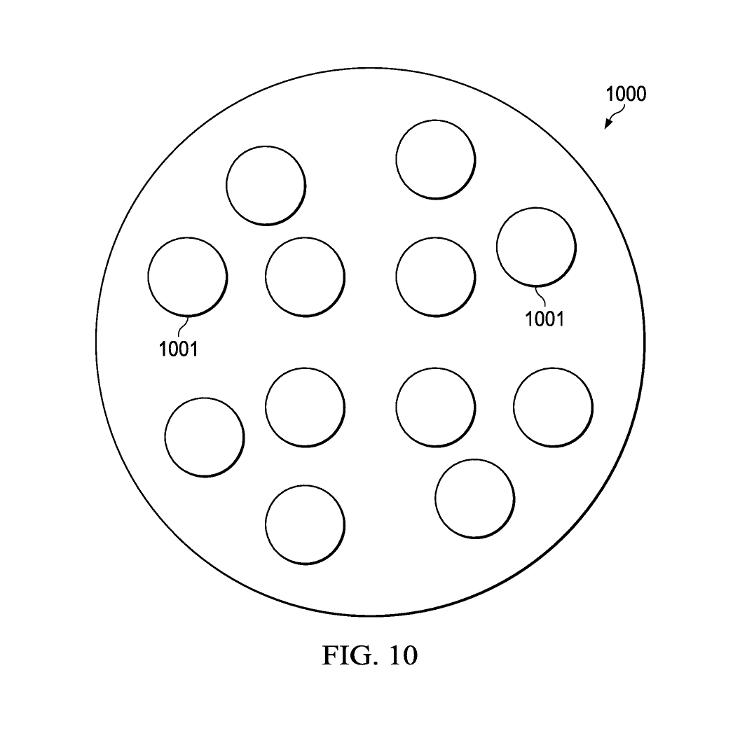

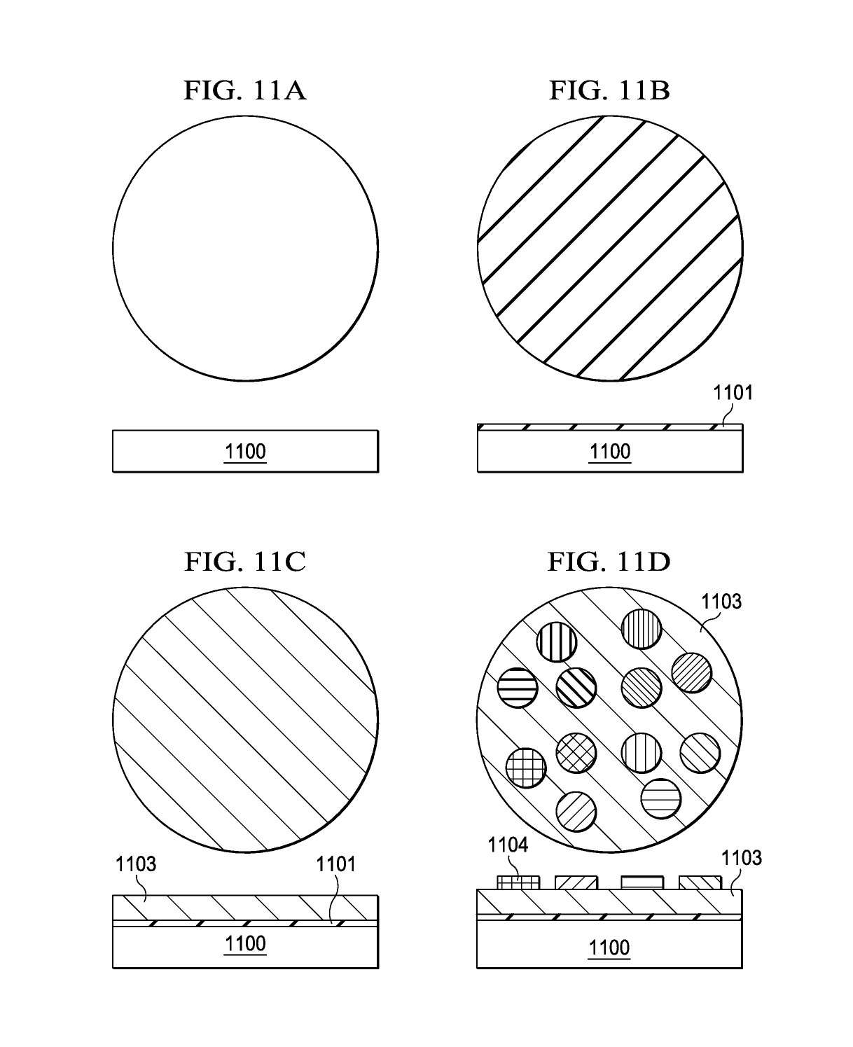

FIGS. 11A-11D illustrate an exemplary deposition sequence for forming multilayer film stacks in a combinatorial fashion. A sequence for forming a simple multilayer film stack comprising a substrate, capping layer, dielectric material, and an electrode material to form a simple capacitor stack will be used as an example. Those skilled in the art will understand that the substrate may already have several layers comprising conductive layers, dielectric layers, or both deposited thereon. FIG. 11A begins with a substrate 1100 which is operable as a first electrode of a capacitor stack.

FIG. 11B illustrates a capping layer 1101 disposed upon the substrate 1100. As previously described, capping layer 1101 can be formed upon substrate 1100 by various methods such as a plasma enhanced CVD method. In some embodiments, the thickness of capping layer 1101 is in the range of 5-15 nanometers.

In some embodiments, the plasma generated during the plasma enhanced CVD process removes (e.g. via a plasma etch) any native or amorphous oxide present on the substrate prior to forming the first capping layer on the film. For example, prior to depositing the first and second capping layers, the substrate's surface is exposed to a plasma and thereby subjected to bombardment by energetic ions whose kinetic energy may vary from a few electron volts (eV) to hundreds of electron volts according to some embodiments.

FIG. 11C illustrates a first material 1103 formed above the substrate 1100 and capping layer 1101 wherein the first material 1103 is operable as a dielectric of a capacitor stack. As illustrated in FIG. 11C, the first material 1103 is uniformly formed across the substrate surface 1100. This may be accomplished using a conventional deposition chamber or may be accomplished using a combinatorial deposition chamber. If a combinatorial deposition chamber is used, then each of the large area showerhead sections, (i.e. as described previously), would be used to deposit the same material using the same process parameters. This results in a uniform formation of the first material 1103.

In FIG. 11D, multiple alternatives of a second material 1104 are formed above the first material 1103 wherein the second material 1104 is operable as the second electrode of the capacitor stack. As illustrated in FIG. 11D, the second material 1104 is deposited in small spots using a plurality of the small spot showerhead apparatus described in detail in U.S. patent application Ser. No. 13/341,993. Advantageously, the plurality of small spot showerhead apparatus is integrated into large area, quadrant showerheads as described previously.

FIG. 11D illustrates twelve electrode experiments. They may represent the combinatorial variation of precursor chemicals, reactant chemicals, precursor/reactant delivery conditions (i.e. flow rates, pressure, pulse times, etc.), electrode thickness, substrate temperature, etc. Each of the twelve capacitors would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measure the equivalent oxide thickness (EOT) of the dielectric material, measuring the concentration and energy levels of traps or interface states, measuring the concentration and mobility of charge carriers, etc.

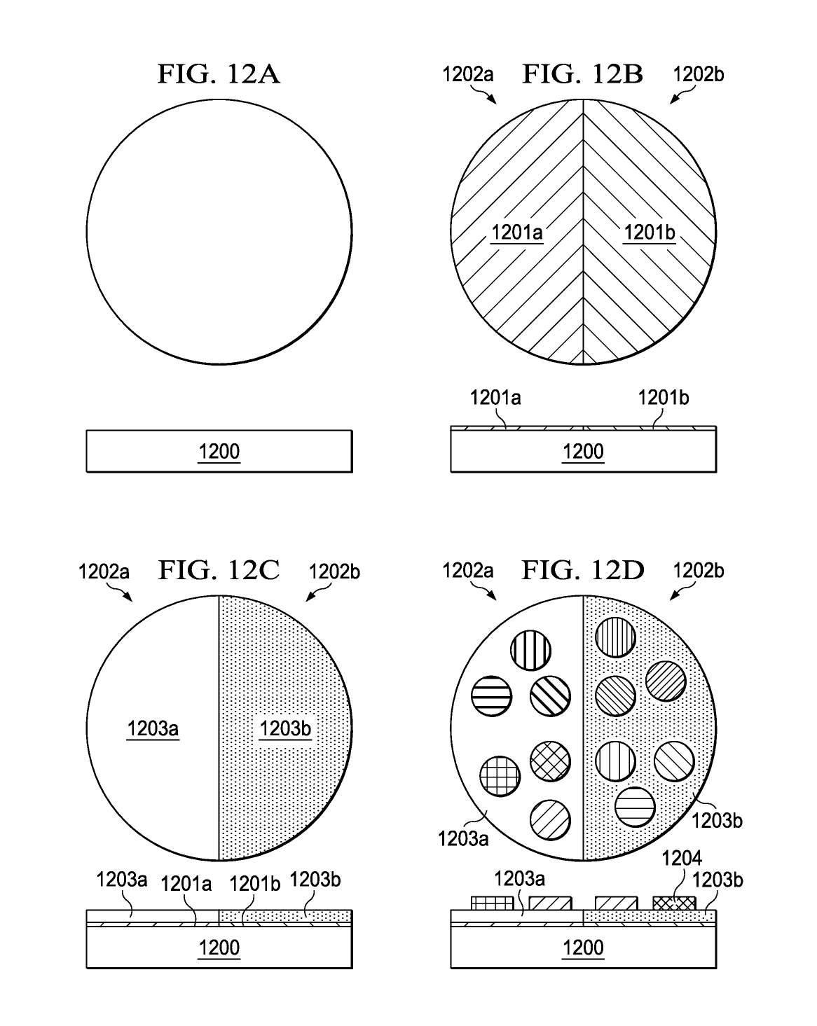

FIGS. 12A-12D illustrates an exemplary deposition sequence for forming multilayer film stacks in a combinatorial fashion. A sequence for forming a simple multilayer film stack comprising a substrate, capping layer, dielectric material, and an electrode material to form a simple capacitor stack will be used as an example. Those skilled in the art will understand that the substrate may already have several layers comprising conductive layers, dielectric layers, or both deposited thereon. FIG. 12A begins with the substrate 1200 which is operable as a first electrode of a capacitor stack.

In some embodiments, the plasma generated during the plasma enhanced CVD process removes (e.g. via a plasma etch) any native or amorphous oxide present on the substrate prior to forming the first and second capping layers on the film. For example, prior to depositing the first and second capping layers, the substrate's surface is exposed to a plasma and thereby subjected to bombardment by energetic ions whose kinetic energy may vary from a few electron volts (eV) to hundreds of electron volts according to some embodiments.

FIG. 12B illustrates a first capping layer 1201a and a second capping layer 1201b disposed upon the substrate 1200 in two different site-isolated regions. As previously described, a first capping layer 1201a and a second capping layer 1201b may be formed upon substrate 1200 by various methods such as a plasma enhanced CVD method. In some embodiments, the first capping layer 1201a and second capping layer 1201b are each in the range of 5-15 nanometers.

In FIG. 12C, two alternatives 1203a, 1203b of a first material are formed above the capping layers 1201a, 1201b disposed on the substrate 1200 wherein the first materials 1203a, 1203b are operable as dielectric materials of capacitor stacks. As illustrated in FIG. 12C, the two alternatives are formed in each of two sections 1202a, 1202b across the substrate surface 1200 respectively which may be accomplished using a combinatorial deposition chamber. In the combinatorial deposition chamber, two of the large area showerhead sections, (i.e. as described previously), would be used to deposit the first alternative 1203a on one half of the substrate 1200 using the same process parameters, and the other two of the large area showerhead sections, (i.e. as described previously), would be used to deposit the second alternative 1203b on the other half of the substrate 1200 using the same process parameters.

In FIG. 12D, multiple alternatives of a second material 1204 are formed above the first material 1203a, 1203b wherein the second material 1204 is operable as the second electrode of the capacitor stack. As illustrated in FIG. 12D, the second material 1204 is deposited in small spots using a plurality of the small spot showerhead apparatus described previously. Advantageously, the plurality of small spot showerhead apparatus are integrated into large area, quadrant showerheads.

FIG. 12D illustrates twelve capacitor experiments. They may represent the combinatorial variation of precursor chemicals, reactant chemicals, precursor/reactant delivery conditions (i.e. flow rates, pressure, pulse times, etc.), electrode thickness, substrate temperature, etc. Each of the twelve capacitors would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measuring the equivalent oxide thickness (EOT) of the dielectric material, measuring the concentration and energy levels of traps or interface states, measuring the concentration and mobility of charge carriers, etc.

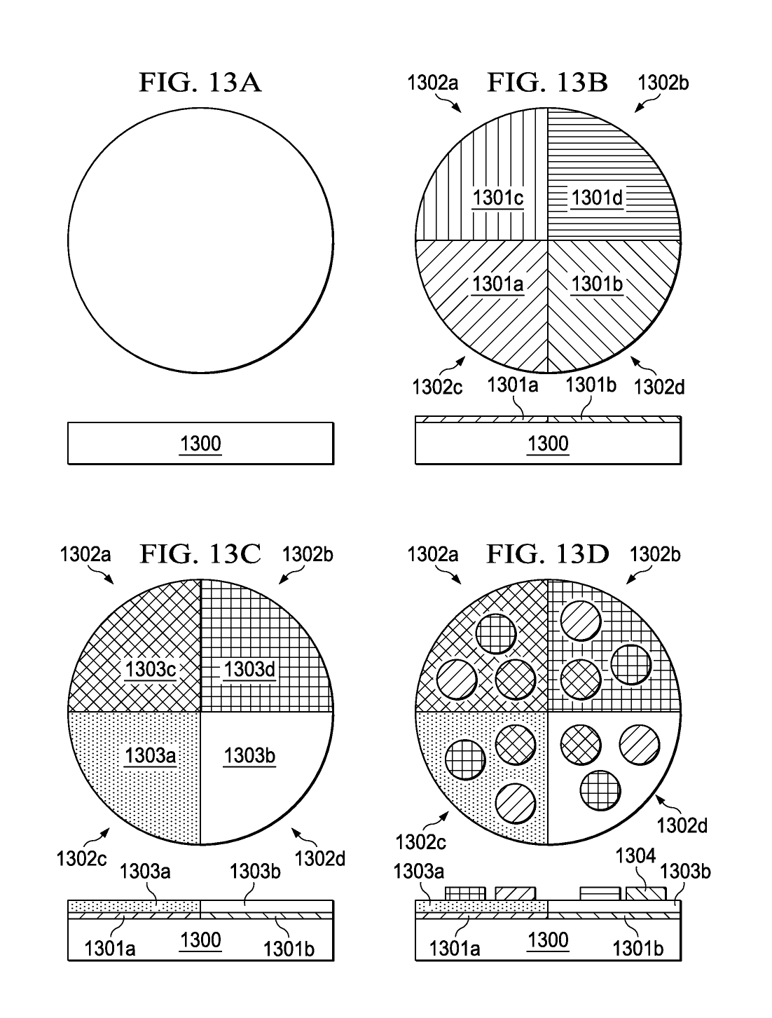

FIGS. 13A-13D illustrates an exemplary deposition sequence for forming multilayer film stacks in a combinatorial fashion. A sequence for forming a simple multilayer film stack comprising a substrate, capping layer, dielectric material, and an electrode material to form a simple capacitor stack will be used as an example. Those skilled in the art will understand that the substrate may already have several layers comprising conductive layers, dielectric layers, or both deposited thereon. FIG. 13A begins with a substrate 1300 which is operable as a first electrode of the capacitor stack.

FIG. 13B illustrates first, second, third, and fourth capping layers 1301a-1301d disposed upon the substrate 1300 in four different site-isolated regions. Capping layers 1301a-1301d enable various tests to determine the optimal capping material and/or processing conditions.

In some embodiments, the plasma generated during the plasma enhanced CVD process removes (e.g. via a plasma etch) any native or amorphous oxide present on the substrate prior to forming the capping layers on the film. For example, prior to depositing the capping layers, the substrate's surface is exposed to a plasma and thereby subjected to bombardment by energetic ions whose kinetic energy may vary from a few electron volts (eV) to hundreds of electron volts according to some embodiments.

Moving forward, FIG. 13C illustrates four alternatives 1303a-1303d of a first material formed above the substrate 1300 wherein the first materials 1303a-1303d are operable as dielectrics a capacitor stack. As illustrated in FIG. 13C, the four alternatives are formed in each of four sections across the substrate surface respectively. This may be accomplished using a combinatorial deposition chamber. In the combinatorial deposition chamber, each of the large area showerhead sections would be used to deposit one of the four alternatives on the substrate.

In FIG. 13D, multiple alternatives of a second material are formed above the first material 1303a-1303d wherein the second material 1304 is operable as the second electrode of the capacitor stack. As illustrated in FIG. 13D, the second material 1304 is deposited in small spots using a plurality of the small spot showerhead apparatus described previously. Advantageously, the plurality of small spot showerhead apparatus are integrated into large area, quadrant showerheads.

FIG. 13D, illustrates twelve capacitor experiments. They may represent the combinatorial variation of precursor chemicals, reactant chemicals, precursor/reactant delivery conditions (i.e. flow rates, pressure, pulse times, etc.), electrode thickness, substrate temperature, etc. Each of the twelve capacitors would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measuring the equivalent oxide thickness (EOT) of the dielectric material, measuring the concentration and energy levels of traps or interface states, measuring the concentration and mobility of charge carriers, etc.

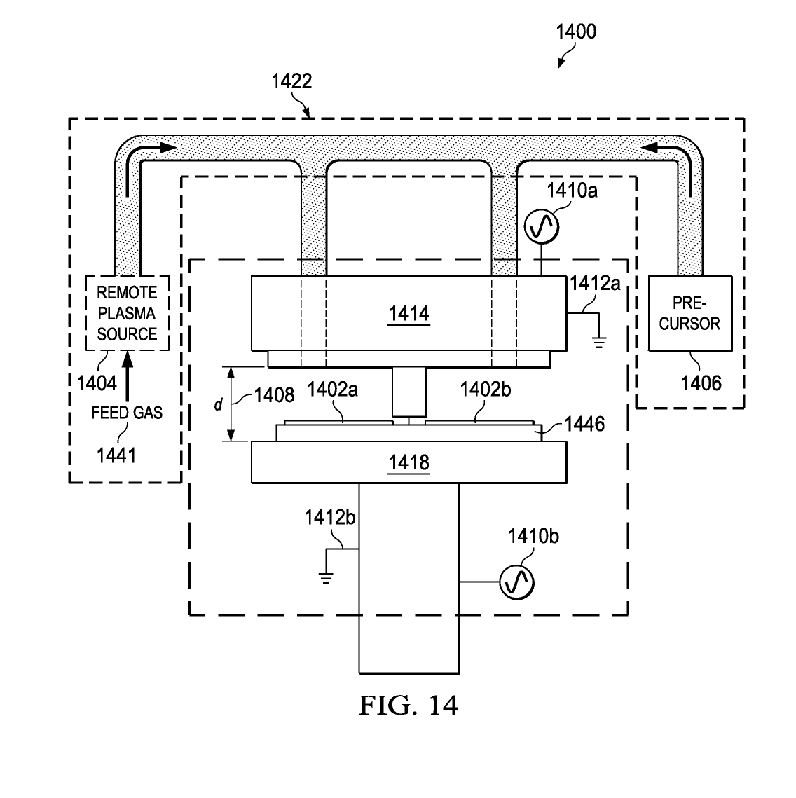

Continuing on through the figures, FIG. 14 shows an illustrative embodiment of an apparatus 1400 enabling combinatorial processing. In particular, FIG. 14 illustrates a processing system 1400 capable of depositing different materials under varying conditions using a plasma-enhanced CVD process. Using the processing system 1400, plasma can be selectively applied to site-isolated regions of the substrate 1446 such that different materials are formed on different site-isolated regions 1402a-1402d (only site-isolated regions 1402a-1402b are shown in the figure) of the substrate 1446. The materials can be considered different if they are formed using varying processing parameters. For example, different precursors can be used in different site-isolated regions, the same precursors can be used but with and without plasma in some site-isolated regions, or some combination of parameters (e.g., RF power, duration, etc.). According to various embodiments, parameters or conditions of PECVD that can be varied for combinatorial processing include power to ignite plasma, flow of plasma and other gases, the type of plasma gas, pressure, selection of precursors, exposure time, spacing, etc.

Plasma can also be used to pre-treat a substrate prior to a PECVD process. Plasma can be used, for example, to remove contamination such as unwanted oxidation on the surface of a substrate. For example, if a copper substrate has surface oxides, the plasma can be applied to remove the unwanted oxides. Other plasma pre-treatments, such as to improve wettability of the substrate, can also be used. The plasma can be applied either to the entire substrate or combinatorially to some site-isolated regions and not to others. Either parameters of the plasma (e.g., plasma gas composition) or the use of plasma versus not using plasma can be varied across site-isolated regions of a substrate and evaluated in a combinatorial process. In some embodiments, combinatorial plasma pre-treatment can be used with subsequent non-combinatorial ALD or CVD processes (i.e., using the same processing conditions across the entire substrate).

Additionally, the entire substrate 1446 may have plasma applied to it, using different precursors or other processing conditions to each site-isolated region of the substrate 1446. As used herein, a material (e.g., comprising a thin film or layer) is different from another material if the materials have different compositions, grain structures, morphologies, thicknesses, etc.

Using plasma to enhance CVD processes can be a combinatorial variable according to various embodiments. Various techniques can be used to provide isolated plasma within the chamber 1400. According to some embodiments described herein, plasma can be provided to individual site-isolated regions (and not to others) of the substrate 1446 via an ex situ application:

Ex situ application of plasma can be performed using a remote plasma source 1404 that generates ions, atoms, radicals and other plasma species. The plasma species from the remote plasma source 1404 are provided to the substrate 1446 using the fluid supply system 1422. The remote plasma source 1404 receives a gas 1441 (i.e., a plasma gas) such as oxygen, hydrogen, ammonia, or argon and generates plasma species such as radicals, ions, atoms, etc. The remote plasma source 1404 can be any type of plasma source such as a radiofrequency, microwave, or electron cyclotron resonance (ECR) upstream plasma source.

The fluid supply system 1422 can deliver fluids from multiple sources. For example, one or more CVD precursors 1406 can be simultaneously or sequentially provided to site-isolated regions 1402a-1402d the substrate 1446. Ex situ plasma can be differentially applied by flowing plasma species to some of the site-isolated regions 1402a-1402d and not to others or by using different plasma characteristics or parameters for different site-isolated regions 1402a-1402d.

According to some embodiments of the disclosure, one segment of the showerhead 1414 can provide a gas that ignites easily (e.g., Ar), while another segment provides a gas that is difficult to ignite (e.g., H₂). Other plasma gases that can be used include oxygen, nitrogen, ammonia, and methane etc. In this way, plasma can be provided to one site-isolated region 1402a-1402d of the substrate 1446, while it is not provided to another site-isolated region 1402a-14-2d. As a result, different materials can be formed in the multiple site-isolated regions 1402a-1402d of the substrate 1446 in a combinatorial manner by varying the plasma. For example, plasma can be used as a reagent in one site-isolated region 1402a of substrate 1446 while another reagent is used in a second site-isolated region 1402b of the substrate 1446. Other techniques for providing plasma to some site-isolated regions of the substrate 1446 and not others are described below.

A voltage difference between the showerhead 1414 and the pedestal 1418 can be provided in several ways. According to some embodiments, a radiofrequency (RF) power source 1410a is attached to one or both of the showerhead 1414 and the pedestal 1418. The RF power source can use any frequency including 2 megahertz (MHz), 3.39 MHz, 13.56 MHz, 60 MHz, 300-500 kilohertz (kHz) and other frequencies. In some embodiments, the showerhead 1414 is powered using the power source 1410a and the pedestal 1418 is attached to ground. In other embodiments, the pedestal 1418 is attached to the power source 1410b and the showerhead is attached to ground 1412a. In a third embodiment, both the showerhead 1414 and the pedestal 1418 are attached to the RF power sources 1410a and 1410b, respectively. With the third embodiment, the power sources 1410a and 1410b can be offset in either or both of frequency or phase.

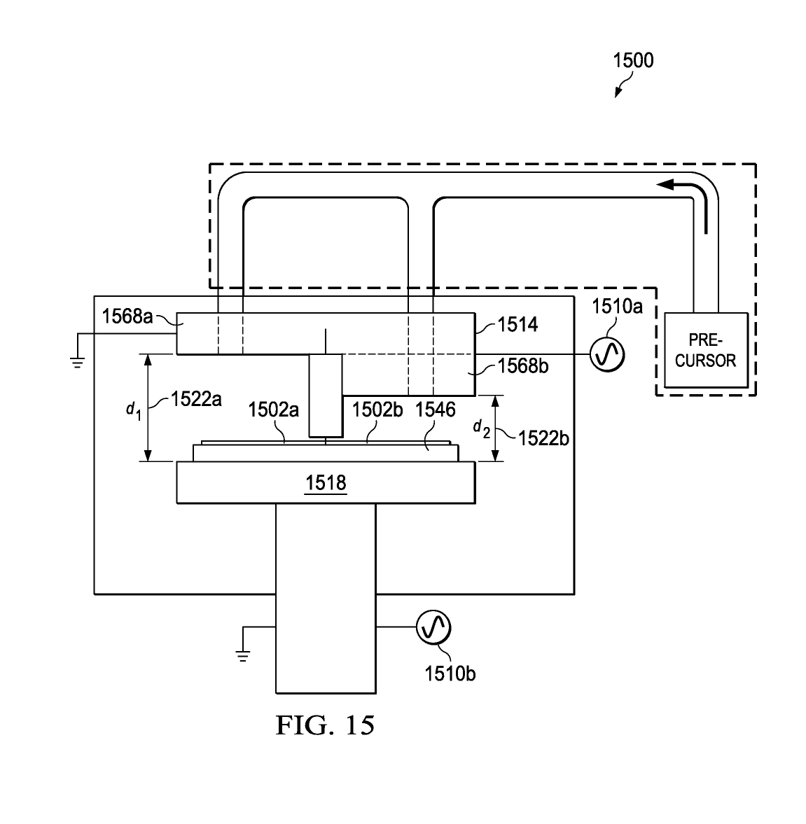

FIG. 15 illustrates a combinatorial processing system 1500 including an alternative showerhead 1514 for performing combinatorial material deposition. As discussed above, the ignition of a plasma (i.e., the breakdown voltage) depends on the distance between the electrodes (e.g., the showerhead 1514 and the pedestal 1518). The alternative showerhead 1514 shown includes segments 1568a and 1568b having different distances (e.g., the distances d₁ 1502a and d₂ 1502b) from the pedestal 1518. A single plasma gas can be fed into the chamber, and the plasma gas and the position of the pedestal can be chosen so that the distance 1502a is too large to ignite a plasma, while the distance 1502b is sufficient to ignite a plasma or vice versa (e.g., the distance 1502a ignites a plasma and the distance 1502b is too small to ignite a plasma). In this way, a plasma can be ignited in some site-isolated regions, and not in others.

According to some embodiments, the segments 1568 can be dynamically movable relative to the substrate 1546. For example, the distances d₁ 1522a and d₂ 1522b can be dynamically adjusted according to the requirements of a particular combinatorial experiment. Additionally, the showerhead 1514 (including the alternative showerhead shown here) can be moved as a unit relative to the substrate 1546 to change the distances d₁ 1522a and d₂ 1522b. Further, either or both of the showerhead 1514 or the pedestal 1518 can be rotatable to alter the distance between the showerhead 1514 and a site-isolated region 1502(a or b) of the substrate 1546 when using the alternative showerhead 1514 shown here.

A plasma can be ignited in one site-isolated region 1502b of a substrate 1546 and subsequently moved to another site-isolated region 1502b to effect combinatorial processing. A technique for moving a plasma from one region to another site-isolated region is described below.

According to some embodiments, the pedestal 1518 can be rotatable. A plasma can be struck in one site-isolated region (e.g., the region 1502a) by providing an appropriate plasma gas through a segment (e.g., the segment 1568a) of the showerhead 1514 corresponding to the site-isolated region. The substrate 1546 can be rotated to transfer the plasma to another site-isolated region (e.g., the site-isolated region 1502b).

In some embodiments, the site-isolated region 1502a can be exposed to a precursor emitted by the segment 1568a and the site-isolated region 1502b can be exposed to a precursor emitted by the segment 1568b. In this example, the segment 1568b is closer to the pedestal 1518 and a plasma ignites in the site-isolated region 1502b, but not in the site-isolated region 1502a. The pedestal 1518 can be rotated to transfer the plasma to the site-isolated region 1502a by moving the site-isolated region 1502a underneath the segment 1568b.

Additionally, the rotation of the pedestal 1518 can be used to create additional site-isolated regions. For example, if the showerhead 1514 is divided into four segments 1568, more than four different materials 1502 can be created on the substrate 1546 by rotating the pedestal 1518. The pedestal can be rotated by ½ a site-isolated region (i.e., 45 degrees) in this example to create eight site-isolated regions. Four precursors can be emitted by the four segments 1568. During the emission of those precursors, the pedestal 1518 can be rotated by 45 degrees to create an additional four site-isolated regions by exposing half of each site-isolated region to another precursor.

For example, precursor A is emitted by segment 1568a onto site-isolated region 1502a, and precursor B is emitted by segment 1568b onto site-isolated region 1502b. During the exposure of the precursors, the pedestal is rotated so that half of site-isolated region 1502a is now exposed to precursor B, while the remainder of site-isolated region 1502a continues to be exposed to precursor A. The resulting eight site-isolated regions include four site-isolated regions exposed to a single precursor and four site-isolated regions that are exposed to a mixture of precursors. It is understood that any number of site-isolated regions combined with any amount of rotation and exposure to precursors can be used to create any number of site-isolated regions.

Methods and apparatuses for combinatorial processing have been described. It will be understood that the descriptions of some embodiments of the present disclosure do not limit the various alternative, modified and equivalent embodiments which may be included within the spirit and scope of the present disclosure as defined by the appended claims. Furthermore, in the detailed description above, numerous specific details are set forth to provide an understanding of various embodiments of the present disclosure. However, some embodiments of the present disclosure may be practiced without these specific details. In other instances, well known methods, procedures, and components have not been described in detail so as not to unnecessarily obscure aspects of the present embodiments.

What is claimed is:

1. A method, comprising:
providing a substrate, the substrate comprising a plurality of site-isolated regions;
forming a first capping layer on the surface of a first site-isolated region of the substrate;
forming a second capping layer on the surface of a second site-isolated region of the substrate wherein forming the first capping layer and the second capping layer includes exposing the first site-isolated region and the second site-isolated region to a plasma induced with H₂ and CH₄ gases;
applying at least one subsequent process to each site-isolated region; and
evaluating results of the application of the at least one process for each site-isolated region.

2. The method of claim 1 further comprising annealing the surface of the first site-isolated region of the substrate and the surface of the second site-isolated region of the substrate.

3. The method of claim 2, wherein the surface of the first site-isolated region and the second site-isolated region are annealed with at least one of NH₃ gas or N₂ gas.

4. The method of claim 1, wherein the at least one subsequent process includes forming a first gate stack on the first capping layer within the first site-isolated region and forming a second gate stack on the second capping layer within the second site-isolated region.

5. The method of claim 1, wherein the plasma is induced with a second hydrocarbon gas.

6. The method of claim 1, wherein the thickness of the first capping layer is five nanometers and the thickness of the second capping layer is ten nanometers.

7. The method of claim 1, wherein the first capping layer and the second capping layer are formed by a plasma enhanced chemical vapor deposition (PECVD) process.

8. The method of claim 1, wherein the substrate comprises a semiconductor material.

9. The method of claim 1 further comprising utilizing the plasma to remove an amorphous and native oxide formed on the substrate.

10. The method of claim 1 further comprising annealing the surface of the first site-isolated region with NH₃ gas and refraining from annealing the surface of the second site-isolated region.

11. The method of claim 1, wherein the substrate is provided in a plasma powered process chamber wherein the plasma power is in the range of 500-1900 Watts within the processing chamber while the first capping layer and the second capping layer are formed.

12. The method of claim 10, wherein the plasma frequency is in the range of 50 KHz-2 GHz.

13. The method of claim 10, wherein the processing chamber has a pressure in the range of 0.1-5 Torr while the first capping layer and the second capping layer are formed.

14. The method of claim 13, wherein the pressure within the processing chamber during the capping layer deposition process is approximately 1 Torr.

15. The method of claim 1, wherein the first capping layer and second capping layer each have a thickness of 10 nanometers.

16. A device, comprising:
a semiconductor substrate (S) having S-Hydrogen bonds at the surface of the semiconductor substrate;
a capping layer disposed on the semiconductor substrate wherein the capping layer comprises carbon atoms and is operable to prevent native oxide from growing on the semiconductor substrate;
a high-k dielectric layer disposed on the capping layer; and
a gate electrode disposed on the high-k dielectric layer.

17. The device of claim 15, wherein the high-k dielectric layer comprises hafnium oxide.

18. The device of claim 16 further comprising at least one of S-Oxygen, S-Carbon, or S-Nitrogen bonds at the surface of the semiconductor substrate.

19. The device of claim 16, wherein the capping layer has a thickness in the range of 5-15 nanometers.

20. The device of claim 15, wherein the capping layer is annealed in NH₃.
